(19) United States
(12) Patent Application Publication
(10) Pub. No.: US 2014/0306290 A1
(43) Pub. Date: Oct. 16, 2014

(54) Dual Silicide Process Compatible with Replacement-Metal-Gate

(71) Applicant: INTERNATIONAL BUSINESS MACHINES CORPORATION, Armonk, NY (US)

(72) Inventors: Emre Alptekin, Wappingers Falls, NY (US); Siyuranga O. Koswatta, Carmel, NY (US); Christian Lavoie, Pleasantville, NY (US); Ahmet S. Ozcan, Pleasantville, NY (US); Kathryn T. Schonenberg, Wappingers Falls, NY (US); Paul M. Solomon, Yorktown Heights, NY (US); Zhen Zhang, Ossining, NY (US)

(73) Assignee: International Business Machines Corporation, Armonk, NY (US)

(21) Appl. No.: 13/860,743

(22) Filed: Apr. 11, 2013

(51) Int. Cl. H01L 21/8238; H01L 27/092

(52) U.S. Cl. CPC H01L 21/823814; H01L 27/092
USPC 257/369; 438/655

(57) ABSTRACT

In one aspect, a method for fabricating an electronic device includes the following steps. A wafer is provided having at least one first active area and at least one second active area defined therein. One or more p-FET/n-FET devices are formed in the active areas, each having a p-FET/n-FET gate stack and p-FET/n-FET source and drain regions. A self-aligned silicide is formed in each of the p-FET/n-FET source and drain regions, wherein the self-aligned silicide in each of the p-FET source and drain regions has a thickness T1 and the self-aligned silicide in each of the n-FET source and drain regions having a thickness T2, wherein T1 is less than T2. During a subsequent trench silicidation in the p-FET/n-FET source and drain regions, the trench silicide metal will diffuse through the thinner self-aligned silicide in the p-FET device(s) but not through the thicker self-aligned silicide in the n-FET device(s).

### FIELD OF THE INVENTION

The present invention relates to dual silicidation techniques and more particularly, to dual silicidation techniques using a combination of self-aligned silicide and trench silicide (and potentially selective masking) in order to reduce overall contact resistance, and which are compatible with a gate-last fabrication process.

### BACKGROUND OF THE INVENTION

Silicide/silicon contact resistance becomes increasingly more dominating in the external resistance of an extremely scaled device. With technologically feasible source and drain epitaxial conditions, along with silicide metallurgy, overall contact resistance is limited by the specific contact resistivity and contact area.

Conventional gate-last fabrication process flows often employ a trench-silicidation scheme for forming source and drain contacts. There are however several notable drawbacks associated with this approach. First, a trench-silicidation scheme is a non-self-aligned contact process. Namely, gate-to-trench overlay requirements along with any misalignment of the trenches with the source and drain regions results in a smaller contact area. A smaller contact area can lead to greater contact resistance. Second, the etch (e.g., reactive ion etching (RIE)) used to form the trenches can also lead to gouging of the underlying source and drain regions. Gouging can lead to material loss that can lead to higher contact resistance as well as strain relaxation that hurts channel mobility.

Therefore, self-aligned silicidation schemes that are compatible with a gate-last fabrication process flow and which mitigate the aforementioned problems would be desirable.

### SUMMARY OF THE INVENTION

The present invention provides dual silicidation techniques using a combination of self-aligned silicide and trench silicide (and potentially selective masking) in order to reduce overall contact resistance, which are compatible with a gate-last fabrication process. In one aspect of the invention, a method for fabricating an electronic device is provided. The method includes the following steps. A wafer is provided having at least one first active area and at least one second active area defined therein. One or more p-channel field effect transistor (p-FET) devices are formed in the first active area and one or more n-channel field effect transistor (n-FET) devices are formed in the second active area, wherein each of the p-FET devices includes a p-FET gate stack over the first active area and p-FET source and drain regions on opposite sides of the p-FET gate stack, and wherein each of the n-FET devices includes an n-FET gate stack over the second active area and n-FET source and drain regions on opposite sides of the n-FET gate stack. A first metal is deposited onto the wafer. The wafer is annealed to form a self-aligned silicide in each of the p-FET source and drain regions and in each of the n-FET source and drain regions from the first metal, wherein the self-aligned silicide has a melting point that is greater than about 1,000° C., and wherein the annealing is performed under conditions sufficient to form the self-aligned silicide in each of the p-FET source and drain regions having a thickness T1 and to form the self-aligned silicide in each of the n-FET source and drain regions having a thickness T2, wherein T1 is less than T2. A filler layer is deposited onto the wafer surrounding the p-FET gate stack and the n-FET gate stack. Trench contact openings are formed in the filler layer over each of the p-FET source and drain regions and over each of the n-FET source and drain regions. A second metal is deposited onto the wafer and lining the trench contact openings. The wafer is annealed to form a trench silicide in each of the p-FET source and drain regions from the second silicide metal, wherein the annealing is performed under conditions sufficient to i) diffuse the second metal through the self-aligned silicide in each of the p-FET source and drain regions to form the trench silicide, and to ii) prevent diffusion of the second metal through the self-aligned silicide in each of the n-FET source and drain regions based on the self-aligned silicide in each of the p-FET source and drain regions being thinner than the self-aligned silicide in each of the n-FET source and drain regions.

A gate-last fabrication process flow may be implemented wherein the p-FET gate stack and the n-FET gate stack are dummy gates. The method may further include the following steps. The p-FET gate stack and the n-FET gate stack may be removed forming trenches in the filler layer. Replacement gate stacks can be formed in the trenches after the self-aligned silicide has been formed and prior to forming the trench contact openings in the filler layer.

In another aspect of the invention, another method for fabricating an electronic device is provided. The method includes the following steps. A wafer is provided having at least one first active area and at least one second active area defined therein. One or more p-FET devices are formed in the first active area and one or more n-FET devices are formed in the second active area, wherein each of the p-FET devices includes a p-FET gate stack over the first active area and p-FET source and drain regions on opposite sides of the p-FET gate stack, and wherein each of the n-FET devices includes an n-FET gate stack over the second active area and n-FET source and drain regions on opposite sides of the n-FET gate stack. The p-FET devices are masked. A first metal is deposited onto the wafer. The wafer is annealed to form a self-aligned silicide in each of the n-FET source and drain regions from the first metal, wherein the masking prevents silicide formation in the p-FET devices and wherein the self-aligned silicide has a melting point that is greater than about 1,000° C. A filler layer is deposited onto the wafer surrounding the p-FET gate stack and the n-FET gate stack. Trench contact openings are formed in the filler layer over each of the p-FET source and drain regions and over each of the n-FET source and drain regions. A second metal is deposited onto the wafer and lining the trench contact openings. The wafer is annealed to form a trench silicide in each of the p-FET source and drain regions from the second metal, wherein silicide formation is prevented in the n-FET devices due to the self-aligned silicide in the n-FET source and drain regions.

In yet another aspect of the invention, yet another method for fabricating an electronic device is provided. The method includes the following steps. A wafer is provided having at least one first active area and at least one second active area defined therein. One or more p-FET devices are formed in the first active area and one or more n-FET devices are formed in the second active area, wherein each of the p-FETs includes a p-FET gate stack over the first active area and p-FET source and drain regions on opposite sides of the p-FET gate stack, and wherein each of the n-FETs includes an n-FET gate stack over the second active area and n-FET source and drain regions on opposite sides of the n-FET gate stack. The p-FET devices are masked. A first metal is deposited onto the wafer. The wafer is annealed to form a self-aligned silicide in each of the n-FET source and drain regions from the first metal, wherein the masking prevents silicide formation in the p-FET devices and wherein the self-aligned silicide has a melting point that is greater than about 1,000° C. A filler layer is deposited onto the wafer surrounding the p-FET gate stack and the n-FET gate stack. First trench contact openings are formed in the filler layer over each of the p-FET source and drain regions. A second metal is deposited onto the wafer and lining the trench contact openings. The wafer is annealed to form a trench silicide in each of the p-FET source and drain regions from the second metal. Second trench contact openings are formed in the filler layer over each of the n-FET source and drain regions.

In still yet another aspect of the invention, an electronic device is provided. The electronic device includes a wafer having at least one first active area and at least one second active area defined therein; one or more p-FET devices formed in the first active area and one or more n-FET devices formed in the second active area, wherein each of the p-FET devices includes a p-FET gate stack over the first active area and p-FET source and drain regions on opposite sides of the p-FET gate stack, and wherein each of the n-FET devices includes an n-FET gate stack over the second active area and n-FET source and drain regions on opposite sides of the n-FET gate stack; a self-aligned silicide formed in each of the p-FET source and drain regions and in each of the n-FET source and drain regions, wherein the self-aligned silicide includes a first metal and has a melting point that is greater than about 1,000° C., and wherein the self-aligned silicide in each of the p-FET source and drain regions has a thickness T1 and the self-aligned silicide in each of the n-FET source and drain regions has a thickness T2, wherein T1 is less than T2; a filler layer on the wafer surrounding the p-FET gate stack and the n-FET gate stack; trench contact openings in the filler layer over each of the p-FET source and drain regions and over each of the n-FET source and drain regions; and a trench silicide formed in the trench contact openings in each of the p-FET source and drain regions, wherein the trench silicide comprises a second metal.

In yet a further aspect of the invention, another electronic device is provided. The electronic device includes a wafer having at least one first active area and at least one second active area defined therein; one or more p-FET devices formed in the first active area and one or more n-FET devices formed in the second active area, wherein each of the p-FET devices includes a p-FET gate stack over the first active area and p-FET source and drain regions on opposite sides of the p-FET gate stack, and wherein each of the n-FET devices includes an n-FET gate stack over the second active area and n-FET source and drain regions on opposite sides of the n-FET gate stack; a self-aligned silicide formed in each of the n-FET source and drain regions, wherein the self-aligned silicide comprises a first metal and has a melting point that is greater than about 1,000° C.; a filler layer on the wafer surrounding the p-FET gate stack and the n-FET gate stack; trench contact openings in the filler layer over each of the p-FET source and drain regions and over each of the n-FET source and drain regions; and a trench silicide formed in the trench contact openings in each of the p-FET source and drain regions, wherein the trench silicide comprises a second metal.

A more complete understanding of the present invention, as well as further features and advantages of the present invention, will be obtained by reference to the following detailed description and drawings.

### BRIEF DESCRIPTION OF THE DRAWINGS

FIG. 1 is a cross-sectional diagram illustrating a starting platform for a silicidation process that includes a wafer in which one or more active areas (corresponding to p-FET and n-FET devices) have been defined, a gate stack having been formed over each of the active areas, and spacers having been formed on opposite sides of each gate stack according to an embodiment of the present invention;

FIG. 2 is a cross-sectional diagram illustrating a high-temperature stable silicide metal having been deposited onto the wafer according to an embodiment of the present invention;

FIG. 3 is a cross-sectional diagram illustrating the high-temperature stable silicide metal having been used to form a high-temperature-stable, self-aligned silicide in the source and drain regions of both the p-FET and the n-FET devices according to an embodiment of the present invention;

FIG. 4 is a cross-sectional diagram illustrating how, with a gate-last approach, a filler layer is deposited onto the wafer and planarized according to an embodiment of the present invention;

FIG. 5 is a cross-sectional diagram illustrating, by way of reference to the exemplary gate-last approach, the dummy gates and the dummy gate oxide having been removed selective to the filler layer and the spacers forming trenches in the filler layer according to an embodiment of the present invention;

FIG. 6 is a cross-sectional diagram illustrating, by way of reference to the exemplary gate-last approach, the trenches in the filler layer having been filled with replacement gate stack materials to form replacement gate stacks according to an embodiment of the present invention;

FIG. 7 is a cross-sectional diagram illustrating a patterned hardmask having been used to pattern trench contact openings in the filler layer over the self-aligned silicide in the source and drain regions of the p-FET and the n-FET devices, and a trench silicide metal having been conformally deposited onto the wafer, filling the trench contact openings according to an embodiment of the present invention;

FIG. 8 is a cross-sectional diagram illustrating an anneal having been used to diffuse the trench silicide metal through the (thinner) self-aligned silicide in the p-FET device(s) to form a trench silicide only in the source and drain regions of the p-FET device(s), followed by removal of unreacted metal according to an embodiment of the present invention;

FIG. 9 is a cross-sectional diagram illustrating contacts having been formed in the trench contact openings according to an embodiment of the present invention;

FIG. 10 is a cross-sectional diagram that follows from FIG. 1 illustrating an exemplary alternative embodiment wherein self-aligned silicide is selectively formed only in the source and drain regions of the n-FET device(s) by forming a hardmask over, covering and thus masking the p-FET device(s) on the wafer during silicidation according to an embodiment of the present invention;

FIG. 11 is a cross-sectional diagram that follows from FIG. 10 illustrating a high-temperature stable silicide metal having been deposited onto the wafer according to an embodiment of the present invention;

FIG. 12 is a cross-sectional diagram that follows from FIG. 11 illustrating the high-temperature stable silicide metal having been used to form a high-temperature-stable, self-aligned silicide in the source and drain regions of the n-FET device(s) according to an embodiment of the present invention;

FIG. 13 is a cross-sectional diagram that follows from FIG. 12 illustrating a patterned hardmask having been used to pattern trench contact openings in a filler layer over the source and drain regions of the p-FET and the n-FET devices (and thus over the self-aligned silicide present only in the n-FET device(s)), and a trench silicide metal having been conformally deposited onto the wafer, filling the trench contact openings according to an embodiment of the present invention;

FIG. 14 is a cross-sectional diagram that follows from FIG. 13 illustrating an anneal having been used to form a trench silicide only in the source and drain regions of the p-FET device(s), followed by removal of unreacted metal according to an embodiment of the present invention;

FIG. 15 is a cross-sectional diagram that follows from FIG. 14 illustrating contacts having been formed in the trench contact openings according to an embodiment of the present invention;

FIG. 16 is a cross-sectional diagram that follows from FIG. 12 illustrating a patterned hardmask having been used to pattern trench contact openings in a filler layer over the source and drain regions of the p-FET device(s) (and blocking/masking the n-FET device(s)), and a trench silicide metal having been conformally deposited onto the wafer, filling the trench contact openings according to an embodiment of the present invention;

FIG. 17 is a cross-sectional diagram that follows from FIG. 16 illustrating an anneal having been used to form a trench silicide only in the source and drain regions of the p-FET device(s), followed by removal of unreacted metal according to an embodiment of the present invention;

FIG. 18 is a cross-sectional diagram that follows from FIG. 17 illustrating a dielectric material having been deposited onto the wafer filling the trench contact openings over the p-FET devices and the dielectric material having been used to pattern the hardmask, and the hardmask in turn having been used to pattern trench contact openings in the filler layer over the n-FET device(s) according to an embodiment of the present invention; and

FIG. 19 is a cross-sectional diagram that follows from FIG. 18 illustrating contacts having been formed in the trench contact openings according to an embodiment of the present invention.

### DETAILED DESCRIPTION OF PREFERRED EMBODIMENTS

As provided above, silicidation process flows incorporating conventional trench-silicidation schemes can have notable drawbacks related to contact resistivity, e.g., reduced contact area due to the non-self-aligned process and potential gouging of the underlying source and drain regions during the trench etch. Advantageously, provided herein are silicidation techniques which avoid these problems by employing a self-aligned, high-temperature-stable silicide in combination with a (subsequent) trench silicide. The self-aligned silicide serves to reduce contact resistance and to protect the source and drain regions during the trench etch. Further, since the self-aligned silicide is high-temperature-stable, the present process can be employed (if so desired) in the context of a self-aligned silicide first, gate-last process flow which can maximize the contact area for a fixed gate pitch.

The implementation of a dual silicide scheme in a silicide first, gate-last process flow is described, for example, in U.S. patent application Ser. No. 13/755,427, filed by Baraskar et al. on Jan. 31, 2013, entitled “Dual Silicide Process,” the entire contents of which are incorporated by reference herein. In general, however, a silicide first, gate-last approach involves forming a dummy gate, performing the silicidation and then replacing the dummy gate with a replacement gate. Forming the replacement gate generally involves a high temperature anneal (e.g., to set the workfunction and/or to improve the reliability of the gate by reducing bias-temperature-instability (BTI) effects). The silicide formed by conventional processes would be degraded during this anneal. By contrast, a high-temperature-stable silicide is employed in the present techniques and thus does not have the same temperature constraints. It is notable however that, as will be described in detail below, the use of a dummy gate/replacement gate scheme is merely one example, and that the present techniques are more generally applicable to any dual silicide process.

Several different exemplary embodiments for forming an electronic device having at least one p-FET and at least one n-FET that includes a dual silicidation scheme are now provided. As highlighted above, the present dual silicidation process involves forming self-aligned, high-temperature-stable silicide contacts on both nFET and pFET devices. The high-temperature stability of the self-aligned silicide permits use of a silicide-first, gate-last approach (if so desired) in which the self-aligned silicide is formed before the replacement gate—followed by formation of a trench silicide after the replacement gate is in place. By way of the present techniques, the self-aligned silicide serves to compensate for the comparatively higher specific contact resistivity (Rho_c) values in the nFET device(s) (as compared to the pFET devices), and a more controlled etch stop in both the nFETs and pFET devices (thus protecting the source and drain regions from gouging).

Subsequently (e.g., after the replacement gate has been formed—if a gate-last approach is followed) a trench silicide is formed on both nFETs and pFETs. This trench silicide can involve conventional silicide metals since the high-temperature process (e.g., such as those associated with the replacement gate formation) have already been performed. The use of a self-aligned silicide in combination with a subsequent trench silicide leads to acceptable contact resistance values in the pFET device(s) which is facilitated by small Rho_c values. As provided above, overall contact resistance is limited by the specific contact resistivity and contact area. Thus, even if misalignment of the trench silicide occurs (which affects contact area), the overall contact resistance with the present devices is lower than conventional products due to the larger contact area attained by use of the self-aligned silicide.

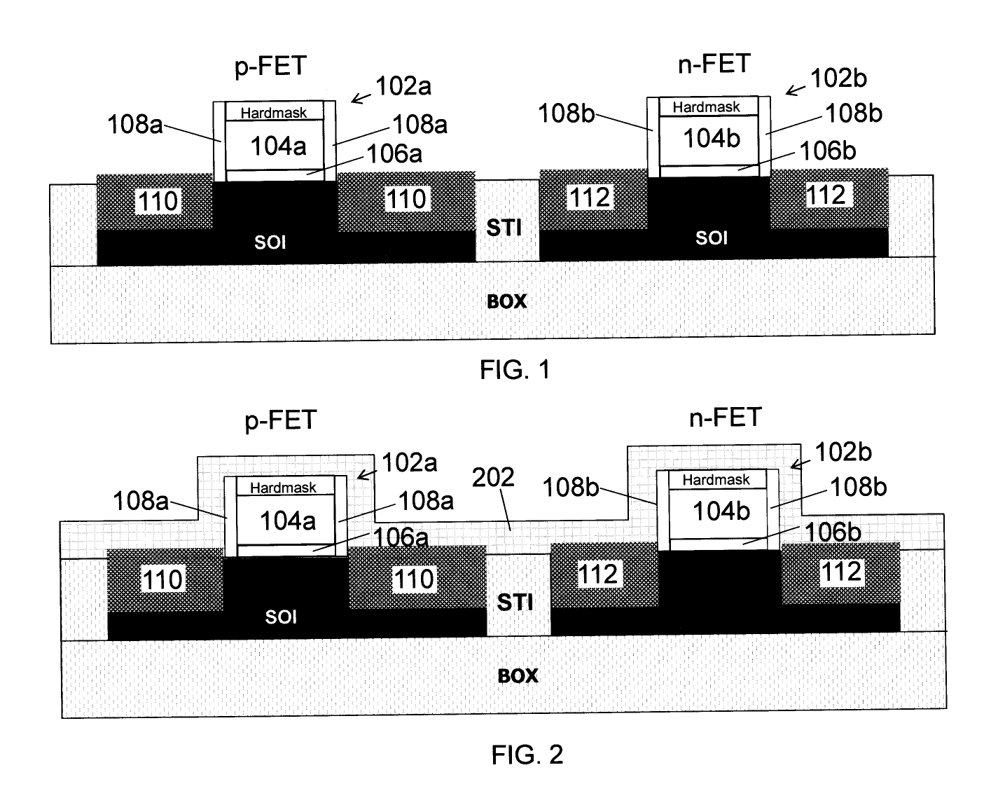

A first exemplary embodiment employing the present techniques will now be described in conjunction with the description of FIGS. 1-9. As shown in FIG. 1, the starting platform for the process is a wafer in which one or more active areas have been defined. For illustrative purposes, the figures provided herein depict the formation of two devices, one p-channel field effect transistor (p-FET) and one n-channel FET (n-FET). Of course the number and/or types of devices formed can vary in accordance with the present teachings, and the configurations shown are chosen merely to illustrate the present silicidation process. Further, in the following description, reference may be made to structures in multiple, e.g., multiple active areas, multiple gate stacks, multiple hardmasks, etc. In such cases, for ease and clarity of description, these structures may also be referred to using the qualifiers first, second, etc., e.g., first active area, second active area, etc.

By way of example only, the starting wafer can be a semiconductor-on-insulator (SOI) wafer or a bulk semiconductor wafer. A SOI wafer includes a SOI layer (e.g., silicon (Si), germanium (Ge), silicon-germanium (SiGe), etc. separated from a substrate by a buried oxide or BOX. See FIG. 1. For ease and clarity of depiction, the underlying substrate is not shown in the figures. With an SOI wafer, the active areas can be defined using a shallow trench isolation (STI) process, where trenches are patterned in the wafer and the trenches are then filled with an insulator to form one or more STI regions. In the SOI wafer example, the STI regions (labeled “STI”) extend through the SOI layer (see, for example, FIG. 1).

Suitable bulk semiconductor wafers include, but are not limited to, bulk Si, Ge, or SiGe wafers. STI can also be used to define active areas in a bulk wafer.

As shown in FIG. 1, a gate stack (i.e., gate stacks 102a, 102b, etc.) has been formed over each of the active areas of the wafer. Each gate stack includes a gate electrode (i.e., gate electrode 104a, 104b, etc.) over a gate dielectric (i.e., gate dielectric 106a, 106b, etc.). By way of example only, the gate electrode may be formed from a metal(s) and/or doped polysilicon. The gate dielectric may be formed from an oxide, such as silicon oxide, or hafnium oxide. High-k dielectrics, such as hafnium oxide, are preferable when a metal gate electrode is employed. It is notable that the configuration of the gate electrode depicted in the figures is merely exemplary. By way of example only, gate stack configurations without a gate dielectric are possible.

The gate stacks may be formed by forming/depositing the gate stack materials (e.g., the gate dielectric, the gate electrode material, etc.) on the wafer and then patterning the materials into the individual gate stacks. A hardmask is used during the patterning. See, for example, FIG. 1. This gate stack hardmask may be left in place to protect the gate stacks during subsequent processing steps. As shown in FIG. 1, spacers (i.e., gate spacer 108a, 108b, etc.) are present, formed on opposite sides of each of the gate stacks. The spacers may be formed by depositing a suitable spacer material, such as silicon nitride, onto the wafer and then patterning the spacer material into the individual spacers shown.

In general, each FET device includes a source region and a drain region interconnected by a channel. The gate stack is located over the channel and regulates electron flow through the channel. The source and drain regions of the device can be formed (on opposite sides of the gate stacks) in-situ or ex-situ (e.g., by way of an ion implantation process) followed by an activation anneal of the dopants. With an in-situ process, dopants can be introduced during the growth of an epitaxial material in the source and drain regions of the device. According to an exemplary embodiment, the source and drain regions 110 of the p-FET device(s) are formed from in-situ boron doped (ISBD) silicon germanium (SiGe). Namely, boron is introduced during growth of a SiGe epitaxial material in the source and drain regions of the p-FET device(s). According to an exemplary embodiment, the source and drain regions 112 of the n-FET device(s) are formed from in-situ phosphorous doped silicon carbon (SiC:P). Namely, phosphorous is introduced during growth of a silicon carbon epitaxial material in the source and drain regions of the n-FET device(s).

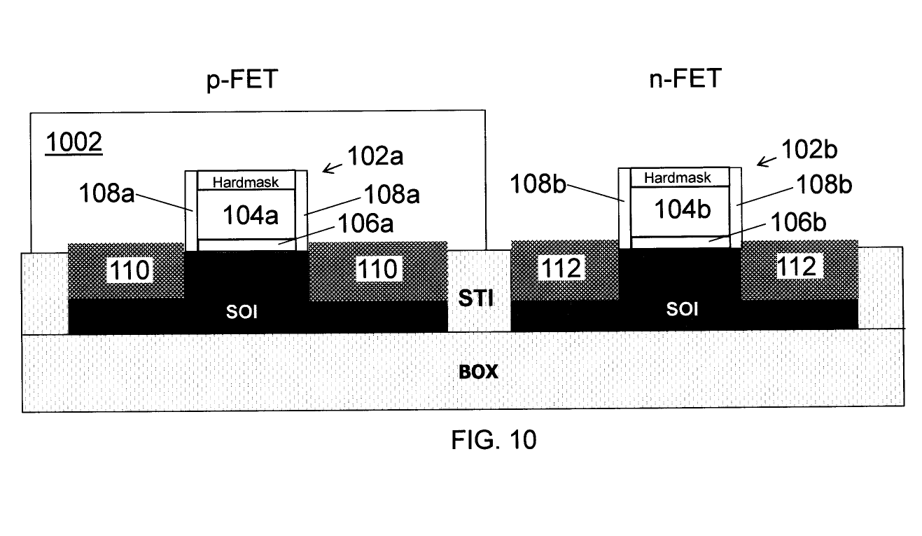

The source and drain doping may be carried out by first masking the p-FET device(s) (or alternatively the n-FET device(s)) and forming the source and drain regions in the n-FET device(s) (or alternatively the p-FET device(s)). The mask is then removed and the process is repeated for the opposite polarity device, again using selective masking. The mask used during this process can be a hardmask formed from a suitable hardmask material, such as silicon nitride that is deposited onto the wafer and then patterned into the selective hardmask using standard lithography and etching techniques. While these hardmasks are not shown in FIG. 1, FIG. 10 shows (in an alternative embodiment) use of such a hardmask during the self-aligned silicidation process. As will be described in detail below, in order to simplify the fabrication process flow, the same hardmask used during the source and drain formation in the n-FET device(s) (i.e., to mask the p-FET devices) can also serve to mask/block the p-FET devices during (self-aligned) silicidation of the n-FET devices—see below.

It is notable that while the instant embodiments are directed to planar devices, the present techniques are applicable, in the same manner described, to non-planar devices, such as FINFET and nanowire FET devices. FINFET devices generally include a source region and a drain region connected by one or more fin-shaped channels. See, for example, U.S. Patent Application Publication Number 2010/0264497 filed by Chang et al., entitled “Multiple Vt Field-Effect Transistor Devices,” the entire contents of which are incorporated by reference herein. A gate covers a portion of the fins that serve as a channel region of the device. Portions of the fins extending out form the gate serve as the source and drain regions of the device. The above-described source and drain epitaxy may, in the context of a FINFET process flow, fully merge, partially merge, or not merge the fins. Nanowire FET devices generally include one or more nanowire channels that interconnect a source and a drain region. A gate covers at least a portion of each of the nanowire channels. When the gate completely surrounds a portion of each of the nanowire channels, this configuration is called a gate-all-around (GAA) structure. See, for example, U.S. Patent Application Publication Number 2012/0007051 filed by Bangsaruntip et al., entitled “Process for Forming a Surrounding Gate for a Nanowire Using a Sacrificial Patternable Dielectric,” the contents of which are incorporated by reference herein.

As described above, due to the use of high-temperature-stable silicide contacts, the present dual silicide process may uniquely be implemented in a gate-last fabrication process flow. In a gate-last process, a dummy gate is formed early on in the process which acts as a placeholder for a replacement gate that, once the dummy gate is removed, will replace the dummy gate. In the case where the present techniques are being implemented in accordance with a gate-last process flow, the gate stacks (i.e., gate stacks 102a, 102b, etc.) shown in FIG. 1 represent the dummy gates. Dummy gates are commonly formed from poly-silicon—and may be patterned in the same manner as described above. A dummy gate dielectric may be employed to permit selective removal of the dummy gates relative to the underlying channel material. In this exemplary gate-last scenario, the gate electrodes (i.e., gate electrodes 104a, 104b, etc.) would be poly-silicon and the gate dielectrics (i.e., gate dielectrics 106a, 106b, etc.) would be an oxide, such as silicon dioxide. As provided above, the use of a gate-last process is only one exemplary configuration, and the present techniques are applicable in the same manner described to other fabrication techniques, such as a gate-first or other suitable approaches. For instance, in a gate-first approach, the gate stacks (i.e., gate stacks 102a, 102b, etc.) shown in FIG. 1 represent the final gates of the devices. Suitable gate electrode and dielectric materials were provided above.

As shown in FIG. 2, a metal 202 is then blanket deposited (e.g., using sputtering or evaporation) onto the wafer, for example, to a thickness of from about 2 nanometers (nm) to about 25 nm. The metal 202 will be used to form a self-aligned silicide contact to the source and drain regions of both the p-FET and the n-FET devices. As provided above, it is preferable that the silicide formed at this stage in the process is resistant to subsequent high-temperature processing (such as an anneal used during replacement gate formation later on in the process). Thus the particular metal or metals chosen are preferably those suitable to form a high-temperature-stable silicide. The term “high-temperature-stable silicide,” as used herein refers to a silicide that is able to withstand (i.e., does not degrade) at temperatures up to about 1,000° C. Suitable metals for use as metal 202 include, but are not limited to, titanium (Ti), cobalt (Co), tantalum (Ta), niobium (Nb), and combinations including at least one of the foregoing metals. These metals may also be referred to herein as “high-temperature stable silicide metals” since they are suitable for forming high-temperature-stable silicide according to the parameters provided above. Namely, the silicides of these exemplary metals have a melting point that is greater than about 1,000 degrees Celsius (° C.).

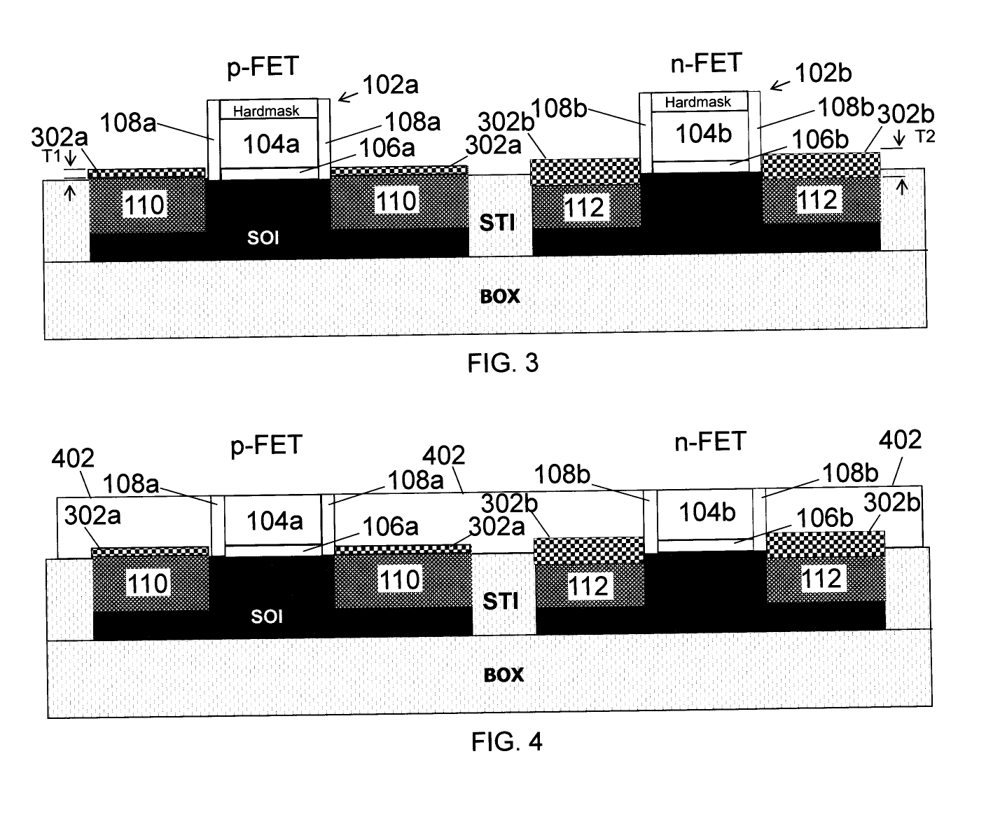

As shown in FIG. 3, the high-temperature stable silicide metal 202 is then used to form a high-temperature-stable, self-aligned silicide (i.e., high-temperature-stable, self-aligned silicide 302a, 302b, etc.) in the source and drain regions of both the p-FET and the n-FET devices, respectively. In general, the silicide process involves using an anneal to form the silicide and then removing the unreacted metal, for example, using a wet etch. The anneal can be performed in a one-step or multi-step process. For example, with a one-step anneal, the silicide-forming anneal can be performed at a temperature of from about 500° C. to about 1,200° C., for a duration of from about 0.1 millisecond (msec) to about 30 minutes, followed by a wet etch to remove the unreacted metal. By way of example only, if a rapid thermal annealing process (RTP) is used then an anneal at a temperature of from about 500° C. to about 800° C., for a duration of from about 1 second to about 30 minutes may be employed. Alternatively, if an ultra-fast anneal (e.g., laser or flash annealing) is used then temperatures of from about 1,000° C. to about 1,200° C. for a duration of from about 0.1 msec to about 5 msec may be employed.

In a two-step anneal, an anneal at a lower temperature (e.g., from about 400° C. to about 800° C.) is performed for a duration of from about 1 second to about 60 seconds, followed by an etch to remove unreacted metal. A second annealing may then be performed at a higher temperature (e.g., from about 600° C. to about 1,000° C.) for a duration of from about 1 second to about 60 seconds, to obtain the desired phase of the silicide material. It is also possible to perform the second step at a higher temperature (e.g., from about 800° C. to about 1,200° C.) for a shorter duration (e.g., from about 0.1 msec to about 5 msec).

According to an exemplary embodiment, it is preferable to attain differential silicide thickness on the p-FET device(s) versus the n-FET device(s). Specifically, the materials (silicide metal(s), deposited thickness, etc.) and/or the silicidation conditions (anneal temperature and/or duration) are chosen such that there is a greater amount (quantified, e.g., based on thickness) of the high-temperature-stable, self-aligned silicide formed in the source and drain regions of the n-FET device(s) as compared to the source and drain regions of the p-FET devices, i.e., a lesser amount of the high-temperature-stable, self-aligned silicide is formed in the source and drain regions of the p-FET devices as compared to the source and drain regions of the n-FET devices. By way of example only, as provided above, the source and drain regions 110 of the p-FET devices may include ISBD SiGe, whereas the source and drain regions 112 of the n-FET devices may include in-situ doped SiC:P. The high-temperature stable silicide metal may be Ti. Using the above-provided metal thickness and annealing parameters, a lesser amount of the high-temperature-stable, self-aligned silicide will be formed in the source and drain regions of the p-FET devices as compared to the source and drain regions of the n-FET devices, since Ti silicide growth on ISBD SiGe pFET source/drain regions is limited compared to that on nFET source/drain regions. Ta when used as the high-temperature stable silicide metal 202 will behave the same as Ti. Using the above conditions, Co will exhibit differential silicide growth since cobalt-silicide does not grow well on SiGe, and thus will be thinner. It is notable that while the source/drain regions of the devices may include materials such as Si, SiGe, and SiC (see above) in order to adhere to conventional terminology the resulting product is referred to generically herein as a “silicide” which is meant to encompass Si-based silicides, SiGe-based germanosilicides, and silicon carbon-based silicides.

The differential silicide thickness will be employed later in the process to permit the subsequent trench silicide to diffuse through the self-aligned silicide in the p-FET device(s), but not so in the n-FET device(s), see below. Thus, according to this exemplary embodiment, the high-temperature-stable, self-aligned silicide 302a formed in the source and drain regions of the p-FET device(s) has a thickness T1 and the self-aligned silicide 302b formed in the source and drain regions of the n-FET device(s) has a thickness T2, wherein T1<T2. According to an exemplary embodiment, T1 (i.e., the thickness of the high-temperature-stable, self-aligned silicide 302a formed in the source and drain regions of the p-FET device(s)) is from about 0.5 nanometers (nm) to about 5 nm, and T2 (i.e., the thickness of the self-aligned silicide 302b formed in the source and drain regions of the n-FET device(s)) is from about 2 nm to about 30 nm.

As highlighted above, the present techniques may advantageously be integrated with a gate-last process flow, and in that case (as detailed above) the gate stacks (i.e., gate stacks 102a, 102b, etc.) present up to this point in the process are called “dummy gates”—e.g., poly-silicon gates that serve as a placeholder and are meant to be removed and replaced with a “replacement” gate. According to an exemplary gate-last approach, in order to permit effective removal and replacement of the dummy gates, a filler layer 402 is deposited onto the wafer and planarized, using for example, chemical-mechanical polishing (CMP). See FIG. 4 wherein the gate stacks are surrounded by the filler layer 402. Suitable filler materials include, but are not limited to, a dielectric material. CMP will serve to remove the hardmasks from over the dummy gates (compare, for example, FIG. 3 and FIG. 4).

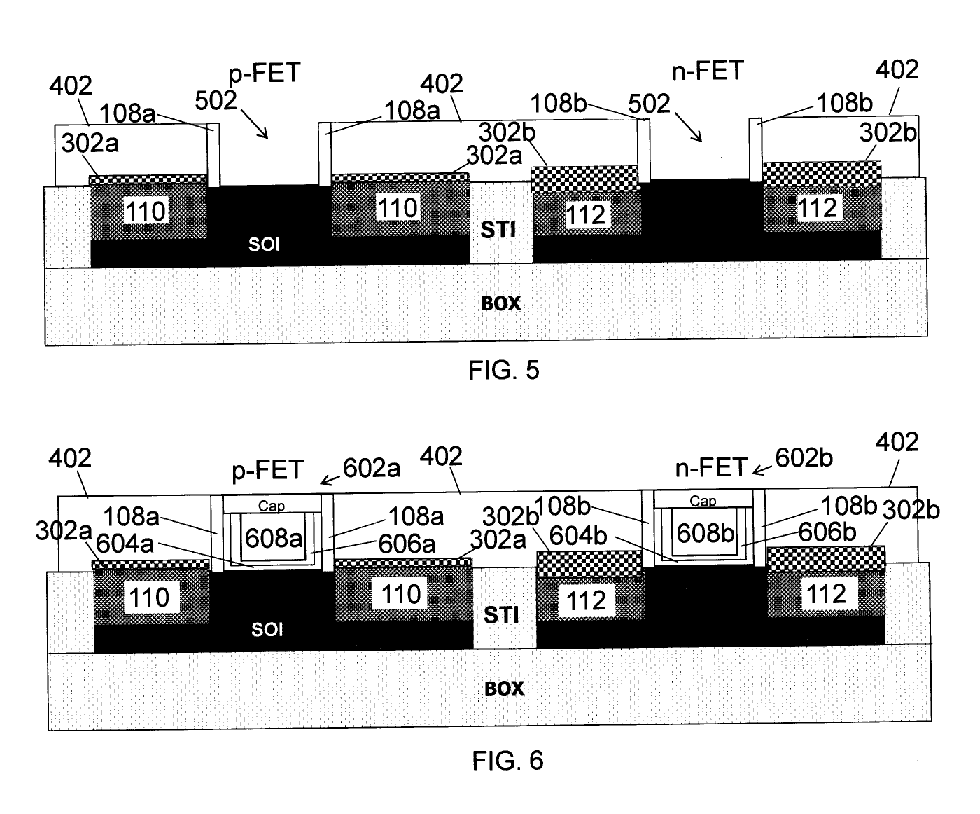

Next, as shown in FIG. 5, the dummy gates and the dummy gate oxide (104a,b and 106a,b, respectively, see above) are removed selective to the filler layer 402 and the spacers 108a,b. According to an exemplary embodiment, the dummy gates are removed using a chemical etching process, such as chemical down stream or potassium hydroxide (KOH) etching, or reactive ion etching (RIE). The dummy gate dielectric is removed after removal of the dummy gates using, for example, wet etches like dilute hydrofluoric (HF) acid or buffered oxide etch (BOE)—when the dummy gate dielectric is an oxide. As shown in FIG. 5, removal of the dummy gates forms trenches 502 in the filler layer.

As shown in FIG. 6, the trenches 502 in the filler layer are then filled with a replacement gate stack material(s) to form replacement gate stacks (i.e., replacement gate stacks 602a, 602b, etc.). Various different replacement gate stack configurations (i.e., materials, structure, etc.) may be employed. Thus, the replacement gate stack structures shown in the figures represent only one possible example. In the exemplary embodiment shown, each of the replacement gate stacks is formed by first depositing a conformal gate dielectric (i.e., gate dielectric 604a, 604b, etc,) into each of the trenches 502 using, for example, a process such as chemical vapor deposition (CVD) or atomic layer deposition (ALD). As described above, suitable gate dielectrics include, but are not limited to, an oxide material, such as silicon oxide, or hafnium oxide.

With a high-k dielectric, such as hafnium oxide, it may be desirable to perform a high-temperature anneal (e.g., at a temperature of from about 900° C. to about 1,200° C.) following deposition of the gate dielectric in order to set the workfunction and/or to improve the reliability of the gate (see above). As provided above, the self-aligned silicide is resistant to high temperatures (due to the use of high-temperature stable silicide metal(s)) and thus is not damaged during this process. This is not so with conventional techniques. Specifically, conventional silicides will agglomerate during this high temperature anneal, damaging the contact. Accordingly, the silicide contacts are typically not formed until late in the process and thus involve multiple masking levels—which add complexity and cost to the manufacturing process along with the drawbacks of the trench-silicide scheme mentioned above.

Following deposition of the gate dielectric, one or more conformal gate metal layers are then deposited into the trenches 502 using, for example, evaporation, sputtering, or atomic layer deposition (ALD). The conformal gate metal layer(s) are represented schematically in the figures as a single conformal layer 606a, 606b, etc. with the understanding that the layer may in fact be composed of multiple conformal metal layers. According to an exemplary embodiment, each of the conformal gate metal layers 606a, 606b, etc. serves as a gate workfunction setting material and as a liner (for the subsequently deposited fill metal—see below). Suitable workfunction setting/liner metals include, but are not limited to lanthanum (La), aluminum (Al), tantalum nitride (TaN), and titanium nitride (TiN). Following deposition of the workfunction setting/liner metal(s), the trenches 502 are then filled with a fill metal (i.e., fill metal 608a, 608b, etc.) using, for example, evaporation, sputtering, or ALD. Suitable fill metals include, but are not limited to, Al and/or tungsten (W). As shown in FIG. 6, it may be desirable to then cap the replacement gate stack, so as to protect the gate stacks during subsequent processing steps. Suitable capping materials include, but are not limited to, silicon nitride (SiN) and silicon dioxide (SiO₂). Replacement gate stacks formed in a gate-last approach are also described, for example, in Martin M. Frank, “High-k/Metal Gate Innovations Enabling Continued CMOS Scaling,” 2011 Proceedings of the European Solid-State Device Research Conference (ESSDERC), 12-16 Sep. 2011, the contents of which are incorporated by reference herein.

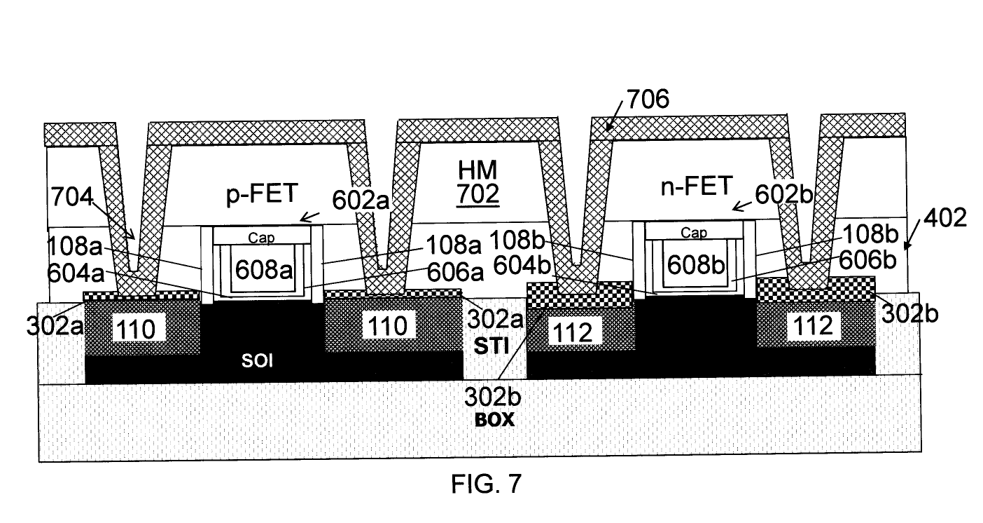

It is notable that the use of a gate last approach is only one possible exemplary implementation of the present techniques. The depiction of a gate last process is provided merely to illustrate its compatibility with the present techniques. The present techniques could however be implemented in the same manner as described above in a gate first (or any other) device fabrication scenario. For instance, in a gate-first scenario, the gate stacks 102a and 102b would constitute the final gates of the device, and beginning with the structure shown illustrated in FIG. 3, a filler layer could be deposited surrounding the gate stacks, in the same manner as described above. However, rather than performing the above-described steps to remove and replace the gate, the process would proceed as illustrated in FIG. 7, described below.

Namely, whether a gate-first or a gate-last approach has been taken, as shown in FIG. 7, the result is a gate stack buried in a filler layer. For consistency in the description, the gate stacks depicted in the figures that follow are that of the replacement gate stacks (i.e., replacement gate stacks 602a, 602b, etc.). However, it is to be understood that if a gate-first process was being employed then the gate stacks employed would be gate stacks 102a, 102b, etc.

The trench silicide contacts to the source and drain regions of the n-FET and p-FET devices are now formed through the filler layer. To begin the trench silicide process, a patterned hardmask 702 is first formed on the filler layer 402 above the gate stacks. By way of example only, the patterned hardmask 702 may be formed from a nitride material, such as silicon nitride. The hardmask may be patterned using conventional lithography and etching techniques.

Next, as shown in FIG. 7, the patterned hardmask 702 is used to pattern trench contact openings 704 in the filler layer 402 over the self-aligned silicide 302a/302b and thus over the source and drain regions 110/112 of the p-FET and the n-FET devices, respectively. The trench contact openings 704 may be patterned in the filler layer 402 using an etching process such as reactive ion etching (RIE). A trench silicide metal 706 is then conformally deposited onto the wafer and into/lining the trench contact openings 704. Thus the same trench contact metal 706 is being used for both the p-FET and n-FET devices. According to an exemplary embodiment, the trench silicide metal 706 includes a metal(s) and/or metal alloy(s) selected from the group including, but not limited to, nickel (Ni), nickel platinum (NiPt), platinum (Pt), and combinations including at least one of the foregoing metal/metal alloys. By way of example only, the trench silicide metal 706 is deposited using a process such as sputtering or evaporation to a thickness of from about 2 nm to about 25 nm.

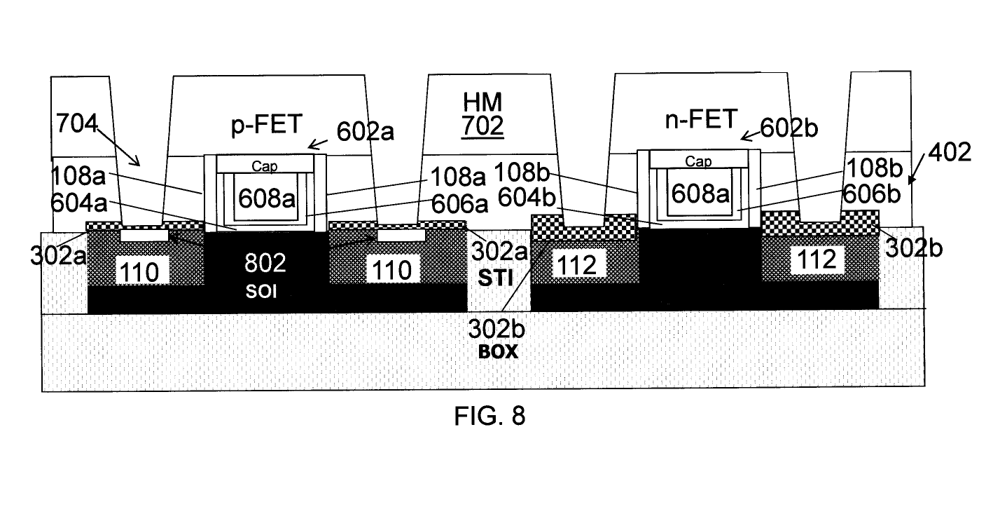

As described above, the self-aligned silicide 302a in the p-FET device(s) source and drain regions is thinner than the self-aligned silicide 302b in the n-FET device(s) source and drain regions. This configuration is employed to now selectively form a trench silicide 802 in the p-FET device(s) (and not in the n-FET device(s)). Specifically, the conditions chosen for forming the trench silicide are such that the trench silicide metal 706 diffuses through the pre-formed (thinner) self-aligned silicide 302a in the p-FET device(s), but not through the (thicker) self-aligned silicide 302b in the n-FET device(s)—i.e., the thickness of the self-aligned silicide 302b in the n-FET device(s) prevents diffusion of the trench silicide metal therethrough. The trench silicide metal 706 that diffuses through the (thinner) self-aligned silicide 302a in the p-FET device(s) will then react with the underlying source/drain material (e.g., ISBD SiGe—see above) to form the trench silicide 802. Accordingly, in this example, the trench silicide 802 will form only in the source and drain regions of the p-FET device(s). See FIG. 8.

Exemplary thickness values of the (thinner) self-aligned silicide 302a and the (thicker) self-aligned silicide 302b were provided in conjunction with the description of FIG. 3 above. Based on those values, conditions that may be employed in order to achieve diffusion of the trench silicide metal selectively through only the (thinner) self-aligned silicide 302a and to form trench silicide 802 are now provided. It is assumed here that the same trench silicide metal is deposited, as described above, to a uniform thickness of from about 2 nm to about 25 nm in both the n-FET and p-FET devices.

As described above, the silicide process involves using an anneal to form the silicide and then removing the unreacted metal, for example, using a wet etch. The anneal can be performed in a one-step or multi-step process. For example, with a one-step anneal, the silicide-forming anneal can be performed at a temperature of from about 400° C. to about 700° C. for a duration of from about 1 second to about 60 seconds, followed by a wet etch to remove the unreacted metal. In a two-step anneal, an anneal at a lower temperature (e.g., from about 280° C. to about 500° C. for a duration of from about 1 second to about 60 seconds) is performed, followed by an etch to remove unreacted metal. A second annealing may then be performed at a higher temperature (e.g., from about 500° C. to about 700° C. for a duration of from about 1 second to about 60 seconds) to obtain the desired phase of the silicide material. It is also possible to perform the second anneal at a higher temperature (e.g., from about 700° C. to about 1,000° C.) for a shorter duration (e.g., from about 0.1 msec to about 5 msec) by using, for example, laser or flash annealing methods.

Thus, according to this example, the only reacted trench metal will be that forming trench silicide 802 in the p-FET device(s). All of the trench silicide metal 706 deposited in the n-FET device(s) will be unreacted and thus removed following the anneal.

It is notable that diffusion of the trench silicide metal through the self-aligned silicide 302b (in the n-FET device(s)) can be slowed due to the presence of carbon in n-FET SiC source and drain regions that is beneficial for the present embodiment. Further, the diffusion of, for example, NiPt through the self-aligned silicide 302a in p-FET device(s) source and drain regions will form NiPt silicide underneath (i.e., the trench silicide 802 will be NiPt silicide). The same is true for the other exemplary trench silicide metals given above. Additionally, the etch (e.g., RIE) used to pattern the trench contact openings 704 in the filler layer 402 (see above) will remove some of the self-aligned silicide in both the n-FET and p-FET devices. By further thinning the self-aligned silicide 302a diffusion of the trench silicide metal 706 through the self-aligned silicide in the p-FET device(s) is insured. Namely, it is notable that the trench RIE may be configured to etch the self-aligned silicide in the p-FET device(s) at a faster rate than the self-aligned silicide in the n-FET device(s) based on the presence of Ge in the p-FET source and drain regions (see, for example, the description of FIG. 1, above). However, even with the same etch rate in the n-FET and p-FET devices, a timed over-etch will remove most of the self-aligned silicide in the p-FET devices (since it is thinner to begin with), while leaving enough silicide on the n-FET device (since it is thicker to begin with).

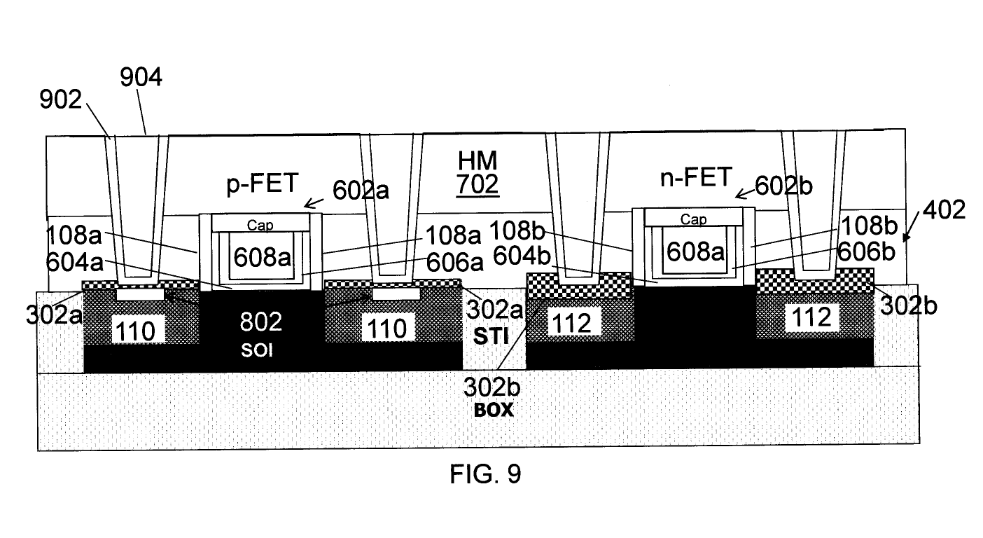

Next, as shown in FIG. 9, contacts are formed in the trench contact openings 704 in contact with the self-aligned silicide (i.e., self-aligned silicide 302a, 302b, etc.) in the source and drain regions of the p-FET and n-FET devices. According to an exemplary embodiment, the contacts are formed by first depositing a liner material 902 into the trenches followed by a fill metal 904. Suitable liner materials include, but are not limited to, CVD or ALD-deposited titanium (Ti), titanium nitride (TiN) and/or tantalum nitride (TaN). Suitable fill metals include, but are not limited to tungsten (W) deposited using evaporation or sputtering. Following the liner and fill metal deposition, chemical mechanical polishing (CMP) may be performed to polish the contacts down to the surface of the hardmask. Any further back-end-of-line (BEOL) processing of the wafer may then be performed.

A second exemplary embodiment employing the present techniques will now be described in conjunction with the description of FIGS. 10-15. This second exemplary embodiment, follows the same basic flow provided in FIGS. 1-9, above, except that instead of employing a (relatively) thinner self-aligned silicide in the p-FET device(s), the p-FET devices receive no self-aligned silicide. Namely, early on in the process when the self-aligned silicide is formed, the p-FET devices are blocked with a hardmask. Thus, self-aligned silicide will be formed only in the n-FET devices, i.e., silicidation is prevented in p-FET device(s) due to the hardmask. Accordingly, during the subsequent trench silicide, there is no self-aligned silicide present in the p-FET device(s) through which the trench silicide metal has to diffuse.

This exemplary embodiment will now be described in detail. The starting structure for this second exemplary embodiment is the same as that shown in FIG. 1 (described in detail above), namely, a wafer in which one or more active areas (corresponding to p-FET and n-FET devices) have been defined and a gate stack having been formed over each of the active areas. The devices, including the source and drain regions 110 and 112 are configured the same as described in conjunction with the description of FIG. 1, above.

In this example, a self-aligned, preferably high-temperature-stable silicide is selectively formed only in the source and drain regions of the n-FET device(s). This is achieved, for example, by forming a hardmask 1002 over, covering and thus masking the p-FET device(s) on the wafer. See FIG. 10, which follows from FIG. 1 wherein the same structures are numbered alike. The hardmask 1002 may be formed by first blanket depositing a suitable hardmask material (such as silicon nitride) and then patterning the hardmask material using conventional lithography and patterning techniques to form hardmask 1002.

As described in conjunction with the description of FIG. 1, above, the source and drain formation may include selectively masking the opposite polarity device(s), forming the source and drain regions, removing the hardmask, and repeating the process for the opposite device type. To simplify the process flow, the hardmask 1002 may serve both for the source and drain formation and for the selective silicidation. By way of example only, a hardmask (not shown) can be selectively formed covering/masking the n-FET devices in the manner described above, allowing the source and drain regions 110 in the p-FET devices to be formed. That mask can be removed, and the hardmask 1002 can then, in the same manner, be formed over, covering and thus masking the p-FET devices (as illustrated in FIG. 10). The source and drain regions 112 can then be formed in the n-FET device(s), followed by the self-aligned silicidation described below (in the n-FET device(s)) using the same hardmask 1002. Alternatively, the source and drain regions 110 and 112 can be formed for both device types first (using selective masking in the manner described above), followed by formation of a separate hardmask 1002 for the silicidation process. In either case, the result would be the device structure shown illustrated in FIG. 10.

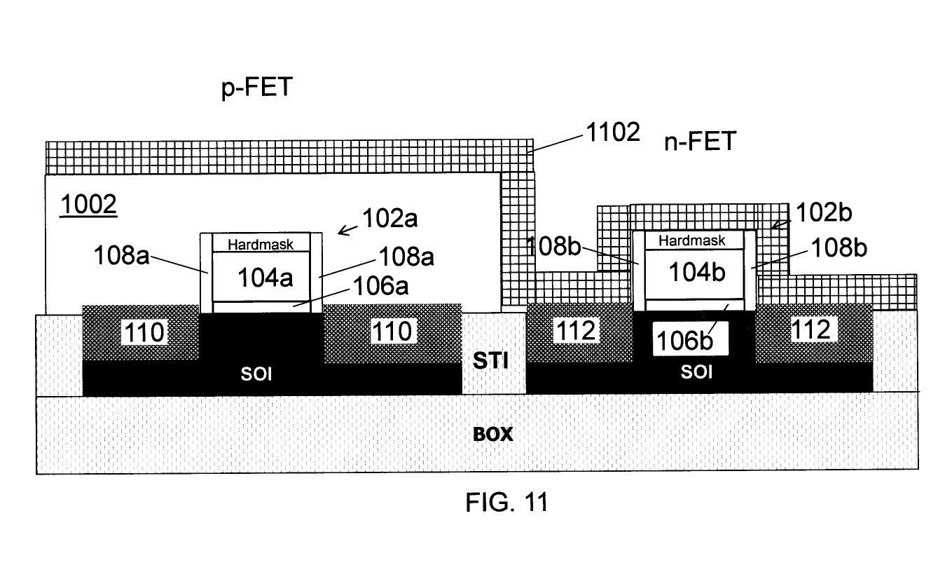

The above-described self-aligned silicidation process is then carried out, this time only in the source and drain regions 112 of the n-FET device(s) (since the p-FET devices are masked by hardmask 1002). Namely, as shown in FIG. 11, a metal 1102 is then blanket deposited (e.g., using sputtering or evaporation) onto the wafer, for example, to a thickness of from about 2 nm to about 25 nm. The metal 1102 will be used to form a self-aligned silicide contact to the source and drain regions of the n-FET device(s). As provided above, it is preferable that the silicide formed at this stage in the process is resistant to subsequent high-temperature processing (such as an anneal used during replacement gate formation later on in the process). Thus the particular metal or metals chosen (e.g., Ti, Co, Ta, and/or Nb) are preferably those suitable to form a high-temperature-stable silicide.

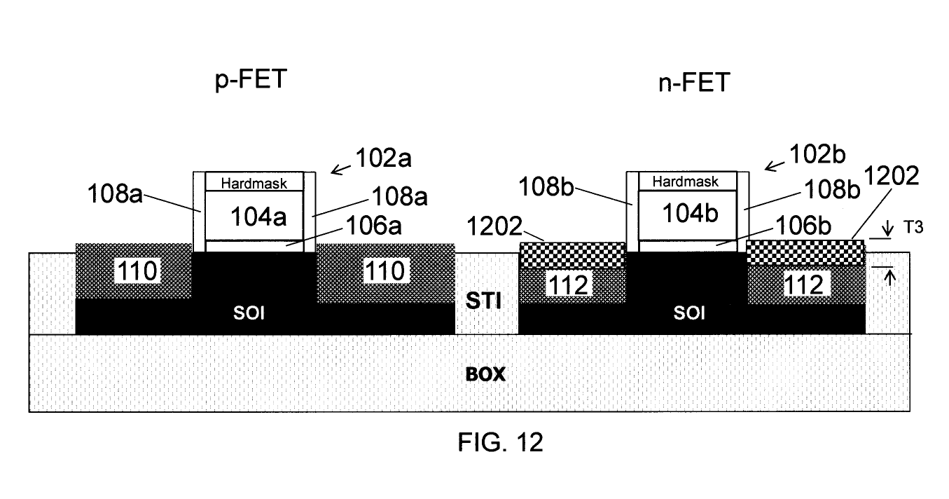

As shown in FIG. 12, the metal 1102 is then used to form a high-temperature-stable, self-aligned silicide (i.e., high-temperature-stable, self-aligned silicide 1202) in the source and drain regions of the n-FET device(s). The parameters for this silicidation process, e.g., one or two step anneal, temperature parameters, etc. were provided above. As described above, a wet etch is then used to remove the unreacted metal, which in this case includes all of the metal 1102 deposited onto the (masked) p-FET device(s). Following removal of the unreacted metal, the hardmask 1002 can then be removed from the p-FET device(s).

According to an exemplary embodiment, the self-aligned silicide 1202 is formed having a thickness T3 of from about 2 nm to about 30 nm. Since there is no self-aligned silicide being formed in the p-FET device(s), the self-aligned silicide 1202 has to be sufficiently thick (e.g., having a thickness T3 in the above-provided range) so to permit a trench silicide to be formed in the p-FET devices without the deposited trench silicide metal diffusing through the self-aligned silicide 1202 in the n-FET device(s)—see below.

The process then proceeds in the same manner as the first embodiment presented above, except that there is no self-aligned silicide present in the p-FET source and drain regions 110. The remainder of the process is now described.

As highlighted above, the present techniques may advantageously be integrated with a gate-last process flow, and in that case the gate stacks present up to this point in the process are called “dummy gates”—e.g., poly-silicon gates that serve as a placeholder and are meant to be removed and replaced with a “replacement” gate. The process for removing the dummy gates and replacing the dummy gates with a replacement gate stack (including depositing a filler layer) were described, in detail, in conjunction with the description of FIGS. 4-6, above. Thus, for ease of description it is assumed that the same steps have been performed here as well, resulting in the formation of replacement gates stacks (i.e., replacement gate stacks 1302a, 1302b, etc.) each having a gate dielectric (i.e., gate dielectric 1304a, 1304b, etc.), a conformal workfunction setting/liner metal(s) (represented schematically in the figures as a single conformal layer 1306a, 1306b, etc. with the understanding that the layer may in fact be composed of multiple conformal metal layers), a fill metal (i.e., fill metal 1308a, 1308b, etc.), and a capping layer. A filler layer 1309 is present surrounding the gate stacks.

As highlighted above, since the previously formed self-aligned silicide 1202 is high-temperature-stable (due to the use of the high-temperature stable silicide metal 1102), the self-aligned silicide can withstand the high temperatures involved in the replacement gate-formation process. Thus, advantageously, the self-aligned silicide 1202 can be formed prior to the replacement gate process, avoiding multiple/complex masking levels commonly associated with conventional dual silicide fabrication flows.

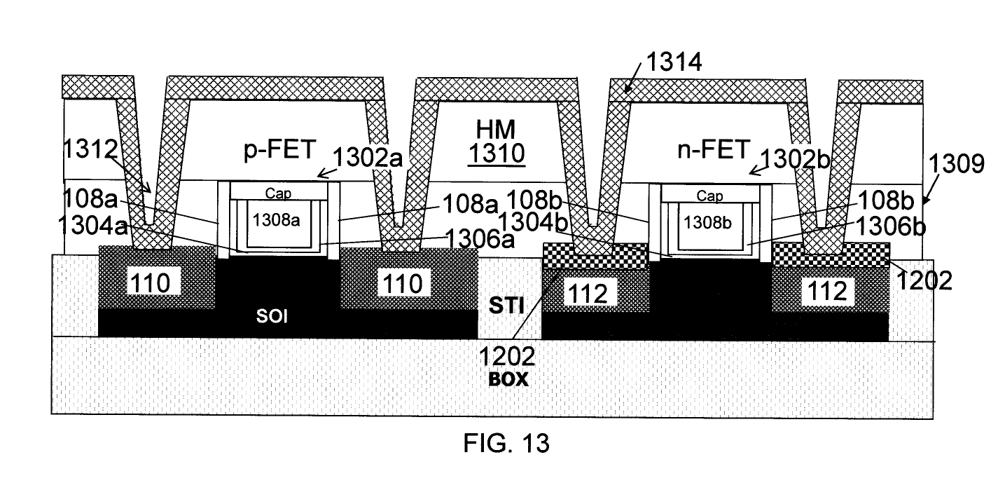

As noted above, the use of a gate last approach is only one possible exemplary implementation of the present techniques. The depiction of a gate last process is provided merely to illustrate its compatibility with the present techniques. The present techniques could however be implemented in the same manner as described above in a gate first (or any other) device fabrication scenario. For instance, in a gate-first scenario, the gate stacks 102a and 102b would constitute the final gates of the device, and beginning with the structure shown illustrated in FIG. 12, a filler layer could be deposited surrounding the gate stacks, in the same manner as described above. However, rather than performing the above-described steps to remove and replace the gate, the process would proceed as illustrated in FIG. 13.

Next, as shown in FIG. 13, trench silicide contacts to the source and drain regions of the n-FET and p-FET devices are now formed through the filler layer. To begin the trench silicide process, a patterned hardmask 1310 (e.g., silicon nitride—patterned in the manner described above) is first formed on the filler layer 1309 above the gate stacks. Next, as shown in FIG. 13, the patterned hardmask 1310 is used to pattern (e.g., using a RIE process) trench contact openings 1312 in the filler layer 1309 over the source and drain regions 110/112 of the p-FET and the n-FET devices. As provided above, there is only a self-aligned silicide (i.e., self-aligned silicide 1202) in the source and drain regions 112 of the n-FET device(s). No preformed silicide is present in the p-FET devices.

A trench silicide metal 1314 (e.g., Ni, NiPt, and/or Pt) is then conformally deposited onto the wafer, and into/lining the trench contact openings 1312. Thus the same trench contact metal 1314 is being used for both the p-FET and n-FET devices. By way of example only, the trench silicide metal 1314 is deposited to a thickness of from about 2 nm to about 25 nm.

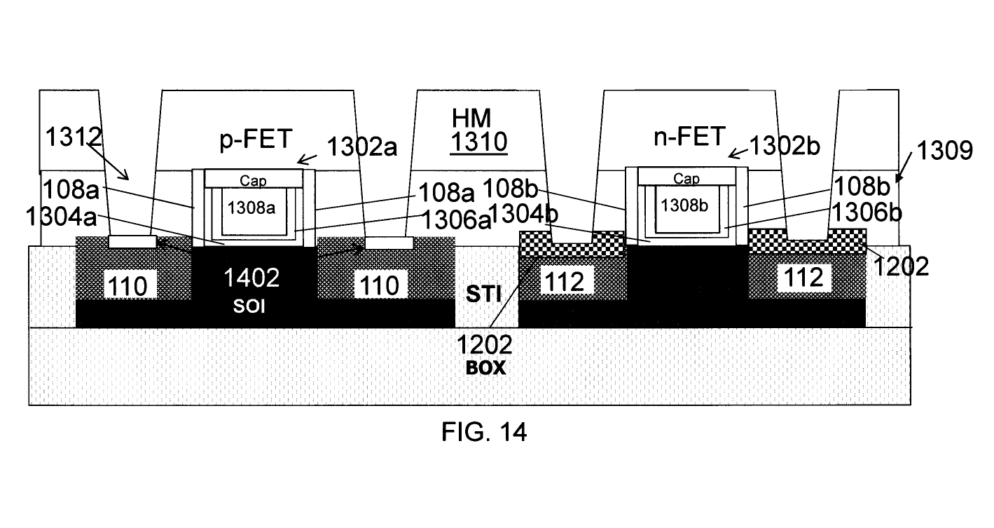

Since there is no pre-formed silicide present in the p-FET device(s), the following silicidation will serve to form a trench silicide 1402 only in the source and drain regions 110 of the p-FET device(s), i.e., the pre-formed self-aligned silicide 1202 in the source and drain regions 112 of the n-FET device(s) will block/prevent any trench silicide from forming in the n-FET device. See FIG. 14.

The conditions chosen for forming the trench silicide are such that the trench silicide metal 1314 forms trench silicide 1402 in the source and drain regions 110 of the p-FET device(s) but does not diffuse through the pre-formed self-aligned silicide 1202 in the n-FET device(s). The trench silicide metal 1314 will react with the underlying source/drain material (e.g., ISBD SiGe—see above) to form the trench silicide 1402. Accordingly, in this example, the trench silicide 1402 will form only in the source and drain regions of the p-FET device(s). See FIG. 14.

It is assumed here that the same trench silicide metal is deposited, as described above, to a uniform thickness of from about 2 nm to about 25 nm in both the n-FET and p-FET devices. Conditions that may be employed in order to form the trench silicide 1402 without having the trench silicide metal 1314 diffuse through the pre-formed self-aligned silicide 1202 (e.g., having a thickness T3 in the above-provided range) in the source and drain regions 112 of the n-FET device(s) are now provided.

As described above, the silicide process involves using an anneal to form the silicide and then removing the unreacted metal, for example, using a wet etch. The anneal can be performed in a one-step or multi-step process. For example, with a one-step anneal, the silicide-forming anneal can be performed at a temperature of from about 400° C. to about 700° C. for a duration of from about 1 second to about 60 seconds, followed by a wet etch to remove the unreacted metal. In a two-step anneal, an anneal at a lower temperature (e.g., from about 280° C. to about 500° C. for a duration of from about 1 second to about 60 seconds) is performed, followed by an etch to remove unreacted metal. A second annealing may then be performed at a higher temperature (e.g., from about 500° C. to about 700° C. for a duration of from about 1 second to about 60 seconds) to obtain the desired phase of the silicide material. It is also possible to perform the second anneal at a higher temperature (e.g., from about 700° C. to about 1,000° C.) for a shorter duration (e.g., from about 0.1 msec to about 5 msec) by using, for example, laser or flash annealing methods.

It is notable that, as described above, diffusion of the trench silicide metal through the self-aligned silicide 1202 (in the n-FET device(s)) can be slowed due to the presence of carbon in n-FET SiC source and drain regions. Further, diffusion of the trench silicide metal through the self-aligned silicide 1202 (in the n-FET device(s)) can be slowed due to the low-temperature RTA used in the trench silicidation process.

According to this example, the only reacted trench metal will be that forming trench silicide 1402 in the p-FET device(s). All of the trench silicide metal 1314 deposited in the n-FET device(s) will be unreacted and thus removed following the anneal.

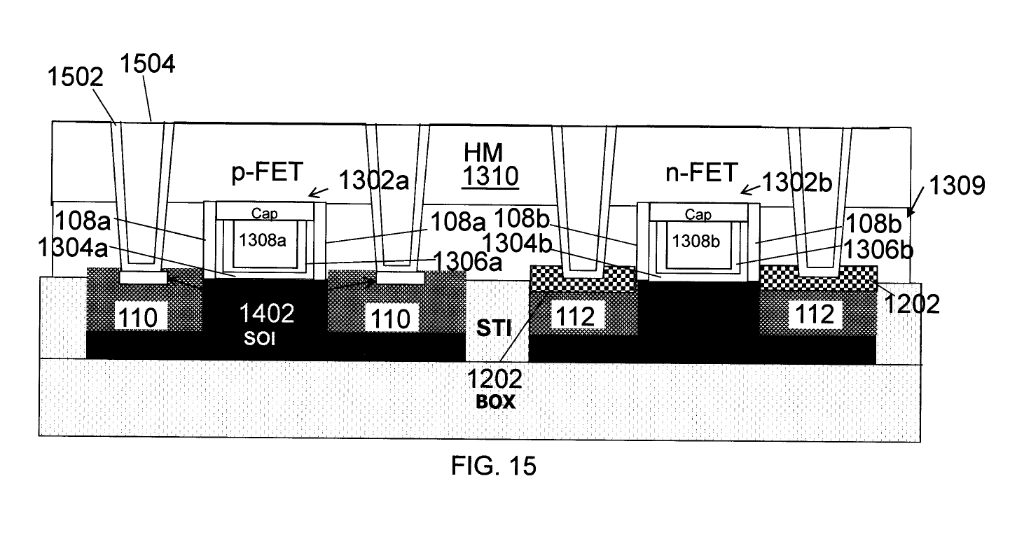

Next, as shown in FIG. 15, contacts are formed in the trench contact openings 1312 in contact with the trench silicide 1402 in the source and drain regions of the p-FET device(s) and with the self-aligned silicide 1202 in the source and drain regions of the n-FET device(s). According to an exemplary embodiment, the contacts are formed by first depositing a liner material 1502 (e.g., CVD or ALD-deposited Ti, TiN and/or TaN) into the trenches followed by a fill metal 1504 (e.g., tungsten (W)). Suitable liner materials include, but are not limited to, CVD or ALD-deposited titanium (Ti), titanium nitride (TiN) and/or tantalum nitride (TaN). Any further back-end-of-line (BEOL) processing of the wafer may then be performed.

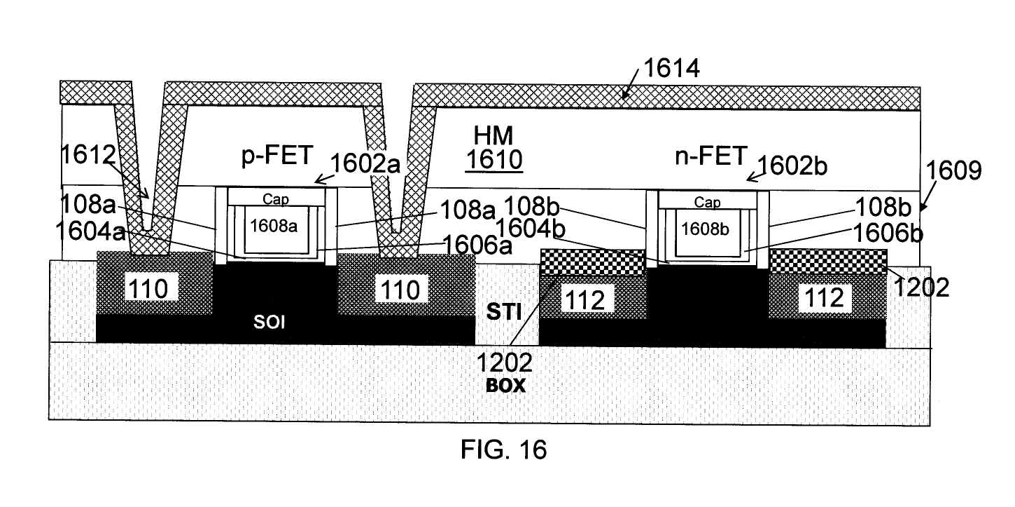

A third exemplary embodiment employing the present techniques will now be described in conjunction with the description of FIGS. 16-19. This third exemplary embodiment is a derivation of the second embodiment (FIGS. 10-15) in which (as with the second embodiment) a hardmask is used to block the p-FET device(s) during the self-aligned silicidation process, such that a self-aligned silicide is formed only in the source and drain regions of the n-FET device(s). However, in this third exemplary embodiment, the subsequent trench silicidation is performed separately for the p-FET and n-FET devices (compare, for example, with FIGS. 13 and 14 of the second exemplary embodiment wherein the trench silicidation is performed for the p-FET and n-FET devices concurrently.

This example begins with the structure shown in FIG. 12 wherein a preferably high-temperature-stable, self-aligned, silicide 1202 has been selectively formed only in the source and drain regions 112 of the n-FET device(s). This configuration may be achieved using the blocking mask procedures described in detail above which are incorporated by reference herein. Beginning with the structure of FIG. 12 wherein the same structures are numbered alike, this third exemplary embodiment is now described in detail.

As highlighted above, the present techniques may advantageously be integrated with a gate-last process flow, and in that case the gate stacks present up to this point in the process are called “dummy gates”—e.g., poly-silicon gates that serve as a placeholder and are meant to be removed and replaced with a “replacement” gate. The process for removing the dummy gates and replacing the dummy gates with a replacement gate stack (including depositing a filler layer) were described, in detail, in conjunction with the description of FIGS. 4-6, above. Thus, for ease of description it is assumed that the same steps have been performed here as well, resulting in the formation of replacement gates stacks (i.e., replacement gate stacks 1602a, 1602b, etc.) each having a gate dielectric (i.e., gate dielectric 1604a, 1604b, etc.), a conformal workfunction setting/liner metal(s) (represented schematically in the figures as a single conformal layer 1606a, 1606b, etc. with the understanding that the layer may in fact be composed of multiple conformal metal layers), a fill metal (i.e., fill metal 1608a, 1608b, etc.), and a capping layer. A filler layer 1609 is present surrounding the gate stacks.

As highlighted above, since the previously formed self-aligned silicide 1202 is high-temperature-stable (due to the use of the high-temperature stable silicide metal 1102), the self-aligned silicide 1202 can withstand the high temperatures involved in the replacement gate-formation process. Thus, advantageously, the self-aligned silicide 1202 can be formed prior to the replacement gate process, avoiding multiple/complex masking levels commonly associated with conventional dual silicide fabrication flows.

As noted above, the use of a gate last approach is only one possible exemplary implementation of the present techniques. The depiction of a gate last process is provided merely to illustrate its compatibility with the present techniques. The present techniques could however be implemented in the same manner as described above in a gate first (or any other) device fabrication scenario. For instance, in a gate-first scenario, the gate stacks 102a and 102b would constitute the final gates of the device, and beginning with the structure shown illustrated in FIG. 12, a filler layer could be deposited surrounding the gate stacks, in the same manner as described above. However, rather than performing the above-described steps to remove and replace the gate, the process would proceed as illustrated in FIG. 16.

In this example, trench contacts will be formed in the p-FET and n-FET devices separately (i.e., in separate steps) through the filler layer. Namely, as shown in FIG. 16, trench silicide contacts to the source and drain regions 110 of the p-FET device(s) are first formed. To begin this trench silicide process, a patterned hardmask 1610 (e.g., silicon nitride—patterned in the manner described above) is first formed on the filler layer 1609 above the gate stacks. Next, as shown in FIG. 16, the patterned hardmask 1610 is used to pattern (e.g., using a RIE process) trench contact openings 1612 in the filler layer 1609 over the source and drain regions 110 of the p-FET device(s). As provided above, there is only a self-aligned silicide (i.e., self-aligned silicide 1202) in the source and drain regions 112 of the n-FET device(s). No preformed silicide is present in the p-FET devices.

In the same manner as described above, a trench silicide metal 1614 (e.g., Ni, NiPt, and/or Pt) is then conformally deposited onto the wafer, and into/lining the trench contact openings 1612. By way of example only, the trench silicide metal 1614 is deposited to a thickness of from about 2 nm to about 25 nm.

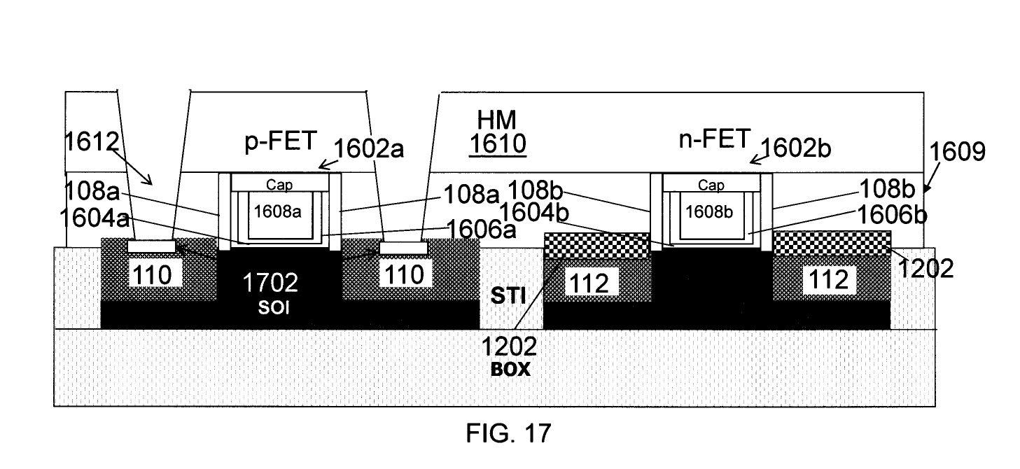

Since the n-FET device(s) are blocked by the patterned hardmask 1610, the following silicidation will serve to form a trench silicide 1702 only in the source and drain regions 110 of the p-FET device(s). See FIG. 17. The trench silicide metal 1614 will react with the underlying source/drain material (e.g., ISBD SiGe—see above) to form the trench silicide 1702. It is assumed here that the same trench silicide metal is deposited, as described above, to a uniform thickness of from about 2 nm to about 25 nm on the p-FET device(s).

As described above, the silicide process involves using an anneal to form the silicide and then removing the unreacted metal, for example, using a wet etch. The anneal can be performed in a one-step or multi-step process. For example, with a one-step anneal, the silicide-forming anneal can be performed at a temperature of from about 400° C. to about 700° C. for a duration of from about 1 second to about 60 seconds, followed by a wet etch to remove the unreacted metal. In a two-step anneal, an anneal at a lower temperature (e.g., from about 280° C. to about 500° C. for a duration of from about 1 second to about 60 seconds) is performed, followed by an etch to remove unreacted metal. A second annealing may then be performed at a higher temperature (e.g., from about 500° C. to about 700° C. for a duration of from about 1 second to about 60 seconds) to obtain the desired phase of the silicide material. It is also possible to perform the second anneal at a higher temperature (e.g., from about 700° C. to about 1,000° C.) for a shorter duration (e.g., from about 0.1 msec to about 5 msec) by using, for example, laser or flash annealing methods.

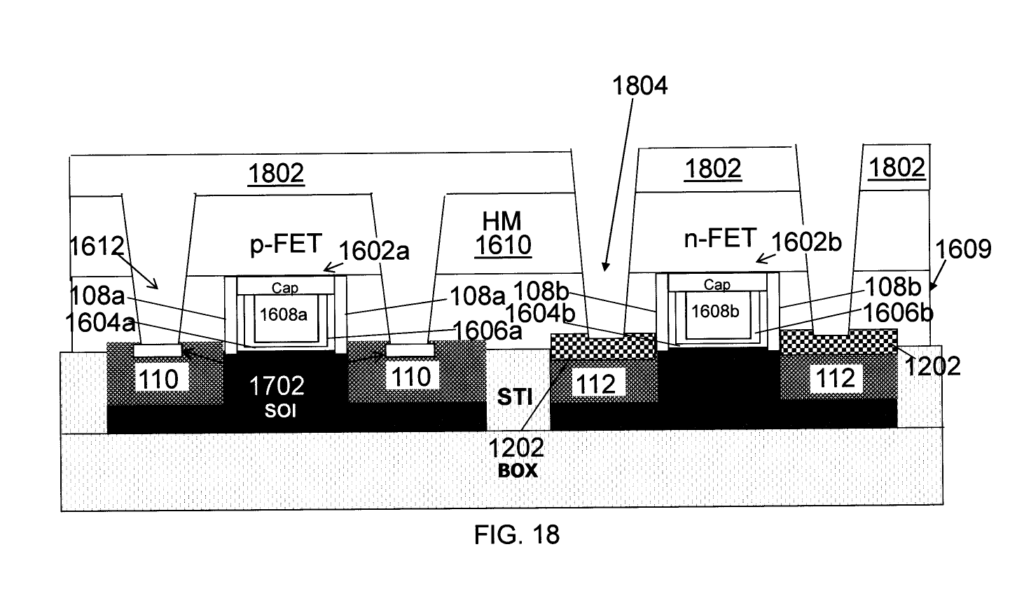

Next, in order to form contact to the n-FET device(s) trench contact openings (i.e., trench contact openings 1804) have to be formed in the filler layer over the source and drain regions 112 of the n-FET devices. In order to protect the trench contact openings 1612 (over the p-FET device(s)) and the trench silicide 1702, a dielectric material 1802 is first deposited onto the wafer, filling the contact openings 1612 over the p-FET device(s). See FIG. 18. According to an exemplary embodiment, the dielectric material 1802 is an organic material. Suitable organic dielectric materials include, but are not limited to, aromatic cross-linkable polymers (e.g., naphthalene-based) in a solvent that may be spin-coated onto the substrate. Spin-coating ensures that the dielectric material 1802 sufficiently fills the trench contact openings 1612.

Other suitable organic materials for use as the dielectric material 1802 include but are not limited to those materials described in U.S. Pat. No. 7,037,994 issued to Sugita et al. entitled “Acenaphthylene Derivative, Polymer, and Antireflection Film-Forming Composition,” U.S. Pat. No. 7,244,549 issued to Iwasawa et al. entitled “Pattern Forming Method and Bilayer Film,” U.S. Pat. No. 7,303,855 issued to Hatakeyama et al. entitled “Photoresist Undercoat-Forming Material and Patterning Process” and U.S. Pat. No. 7,358,025 issued to Hatakeyama entitled “Photoresist Undercoat-Forming Material and Patterning Process.” The contents of each of the foregoing patents are incorporated by reference herein. A post-apply bake is then performed to cross-link the organic dielectric material 1802 and bake off the solvent. According to an exemplary embodiment, the post-apply bake is conducted at a temperature of up to about 250° C., e.g., from about 200° C. to about 250° C.

Next, as shown in FIG. 18, the dielectric material 1802 is patterned, and then used as an etch mask to further pattern the patterned hardmask 1610. The patterned hardmask 1610 is in turn used to pattern trench contact openings 1804 in the filler layer 1609 over the source and drain regions 112 of the n-FET device(s). Patterning of the dielectric material 1802 can involve a hardmask (not shown) such as a low temperature oxide or silicon-containing anti-reflective coating (SiARC)). This patterning of the dielectric material 1802/hardmask 1610/filler layer 1609 may be carried out using a series of selective RIE steps, each step having a chemistry selective for the layer being etched. Following the formation of the trench contact openings 1804 in the filler layer 1609 over the source and drain regions 112 of the n-FET device(s), the dielectric material 1802 is removed using, e.g., a wet etching process.

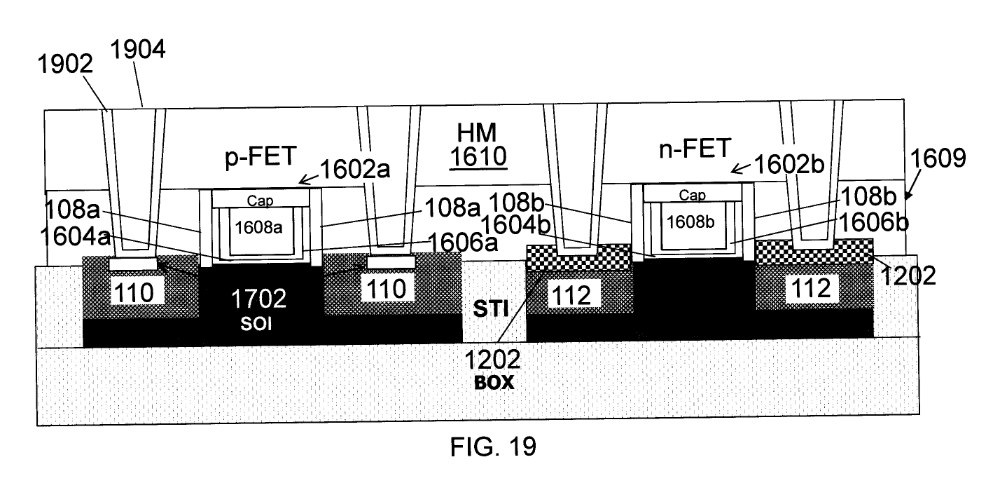

As shown in FIG. 19, following removal of the dielectric material 1802 from the wafer, contacts are formed for the p-FET and n-FET devices concurrently, in the same manner as described above. The contacts formed in the trench contact openings 1612 are in contact with the trench silicide 1702 in the source and drain regions of the p-FET device(s), and the contacts formed in the trench contact openings 1804 are in contact with the self-aligned silicide 1202 in the source and drain regions of the n-FET device(s). According to an exemplary embodiment, the contacts are formed by first depositing a liner material 1902 (e.g., CVD or ALD-deposited Ti, TiN and/or TaN) into the trenches followed by a fill metal 1904 (e.g., tungsten (W)). Suitable liner materials include, but are not limited to, CVD or ALD-deposited Ti, TiN and/or TaN. Any further back-end-of-line (BEOL) processing of the wafer may then be performed.

Although illustrative embodiments of the present invention have been described herein, it is to be understood that the invention is not limited to those precise embodiments, and that various other changes and modifications may be made by one skilled in the art without departing from the scope of the invention.

1. A method of fabricating an electronic device, the method comprising the steps of:
providing a wafer having at least one first active area and at least one second active area defined therein;
forming one or more p-channel field effect transistor (p-FET) devices in the first active area and one or more n-channel field effect transistor (n-FET) devices in the second active area, wherein each of the p-FET devices includes a p-FET gate stack over the first active area and p-FET source and drain regions on opposite sides of the p-FET gate stack, and wherein each of the n-FET devices includes an n-FET gate stack over the second active area and n-FET source and drain regions on opposite sides of the n-FET gate stack;
depositing a first metal onto the wafer;
annealing the wafer to form a self-aligned silicide in each of the p-FET source and drain regions and in each of the n-FET source and drain regions from the first metal, wherein the self-aligned silicide has a melting point that is greater than about 1,000° C., and wherein the annealing is performed under conditions sufficient to form the self-aligned silicide in each of the p-FET source and drain regions having a thickness T1 and to form the self-aligned silicide in each of the n-FET source and drain regions having a thickness T2, wherein T1 is less than T2;
depositing a filler layer onto the wafer surrounding the p-FET gate stack and the n-FET gate stack;
forming trench contact openings in the filler layer over each of the p-FET source and drain regions and over each of the n-FET source and drain regions;
depositing a second metal onto the wafer and lining the trench contact openings; and
annealing the wafer to form a trench silicide in each of the p-FET source and drain regions from the second metal, wherein the annealing is performed under conditions sufficient to i) diffuse the second silicide metal through the self-aligned silicide in each of the p-FET source and drain regions to form the trench silicide, and to ii) prevent diffusion of the second silicide metal through the self-aligned silicide in each of the n-FET source and drain regions based on the self-aligned silicide in each of the p-FET source and drain regions being thinner than the self-aligned silicide in each of the n-FET source and drain regions.

2. The method of claim 1, wherein the p-FET source and drain regions comprise in-situ boron doped (ISBD) silicon germanium (SiGe).

3. The method of claim 1, wherein the n-FET source and drain regions comprise in-situ phosphorous doped silicon carbon (SiC:P).

4. The method of claim 1, wherein the first metal is selected from the group consisting of: titanium (Ti), cobalt (Co), tantalum (Ta), niobium (Nb), and combinations comprising at least one of the foregoing metals.

5. The method of claim 1, wherein the first metal is deposited onto the wafer to thickness of from about 2 nm to about 25 nm.

6. The method of claim 1, wherein the conditions sufficient to form the self-aligned silicide in each of the p-FET source and drain regions having a thickness T1 and to form the self-aligned silicide in each of the n-FET source and drain regions having a thickness T2, wherein T1 is less than T2 comprise annealing the wafer at a temperature of from about 500° C. to about 1,200° C., for a duration of from about 0.1 milliseconds to about 30 minutes.

7. The method of claim 1, wherein the conditions sufficient to form the self-aligned silicide in each of the p-FET source and drain regions having a thickness T1 and to form the self-aligned silicide in each of the n-FET source and drain regions having a thickness T2, wherein T1 is less than T2 comprise a) annealing the wafer at a first temperature of from about 400° C. to about 800° C., for a duration of from about 1 second to about 60 seconds, and b) annealing the wafer at a second temperature of from about 600° C. to about 1,000° C., for a duration of from about 1 second to about 60 seconds.

8. The method of claim 1, wherein the p-FET gate stack and the n-FET gate stack are dummy gates, the method further comprising the steps of:
removing the p-FET gate stack and the n-FET gate stack forming trenches in the filler layer; and
forming replacement gate stacks in the trenches, wherein the replacement gate stacks are formed after the self-aligned silicide has been formed and prior to forming the trench contact openings in the filler layer.

9. The method of claim 1, further comprising the step of:
forming contacts in the trench contact openings.

10. The method of claim 1, wherein the self-aligned silicide formed in each of the p-FET source and drain regions has a thickness T1 of from about 0.5 nanometers to about 5 nanometers, and wherein the self-aligned silicide formed in each of the n-FET source and drain regions has a thickness T2 of from about 2 nanometers to about 30 nanometers.

11. The method of claim 1, wherein the second metal comprises a metal or metal alloy selected from the group consisting of: nickel (Ni), nickel platinum (NiPt), platinum (Pt), and combinations comprising at least one of the foregoing metals and metal alloys.

12. The method of claim 1, wherein the conditions sufficient to i) diffuse the second metal through the self-aligned silicide in each of the p-FET source and drain regions to form the trench silicide, and to ii) prevent diffusion of the second metal through the self-aligned silicide in each of the n-FET source and drain regions comprise annealing the wafer at a temperature of from about 400° C. to about 700° C., for a duration of from about 1 second to about 60 seconds.

13. A method of fabricating an electronic device, the method comprising the steps of:
providing a wafer having at least one first active area and at least one second active area defined therein;
forming one or more p-FET devices in the first active area and one or more n-FET devices in the second active area, wherein each of the p-FET devices includes a p-FET gate stack over the first active area and p-FET source and drain regions on opposite sides of the p-FET gate stack, and wherein each of the n-FET devices includes an n-FET gate stack over the second active area and n-FET source and drain regions on opposite sides of the n-FET gate stack;
masking the p-FET devices;
depositing a first metal onto the wafer;
annealing the wafer to form a self-aligned silicide in each of the n-FET source and drain regions from the first metal, wherein the masking prevents silicide formation in the p-FET devices and wherein the self-aligned silicide has a melting point that is greater than about 1,000° C.;
depositing a filler layer onto the wafer surrounding the p-FET gate stack and the n-FET gate stack;
forming trench contact openings in the filler layer over each of the p-FET source and drain regions and over each of the n-FET source and drain regions;
depositing a second metal onto the wafer and lining the trench contact openings; and
annealing the wafer to form a trench silicide in each of the p-FET source and drain regions from the second metal, wherein silicide formation is prevented in the n-FET devices due to the self-aligned silicide in the n-FET source and drain regions.

14. The method of claim 13, wherein the self-aligned silicide formed in each of the n-FET source and drain regions has a thickness T3 of from about 2 nanometers to about 30 nanometers.

15. The method of claim 13, wherein the p-FET source and drain regions comprise in-situ boron doped (ISBD) silicon germanium (SiGe), and the n-FET source and drain regions comprise in-situ phosphorous doped silicon carbon (SiC:P).

16. The method of claim 13, wherein the first metal is selected from the group consisting of: titanium (Ti), cobalt (Co), tantalum (Ta), niobium (Nb), and combinations comprising at least one of the foregoing metals.

17. The method of claim 13, wherein the p-FET gate stack and the n-FET gate stack are dummy gates, the method further comprising the steps of:
removing the p-FET gate stack and the n-FET gate stack forming trenches in the filler layer; and
forming replacement gate stacks in the trenches, wherein the replacement gate stacks are formed after the self-aligned silicide has been formed and prior to forming the trench contact openings in the filler layer.

18. The method of claim 13, further comprising the step of:
forming contacts in the trench contact openings.

19. A method of fabricating an electronic device, the method comprising the steps of:
providing a wafer having at least one first active area and at least one second active area defined therein;
forming one or more p-FET devices in the first active area and one or more n-FET devices in the second active area, wherein each of the p-FETs includes a p-FET gate stack over the first active area and p-FET source and drain regions on opposite sides of the p-FET gate stack, and wherein each of the n-FETs includes an n-FET gate stack over the second active area and n-FET source and drain regions on opposite sides of the n-FET gate stack;
masking the p-FET devices;
depositing a first metal onto the wafer;
annealing the wafer to form a self-aligned silicide in each of the n-FET source and drain regions from the first metal, wherein the masking prevents silicide formation in the p-FET devices and wherein the self-aligned silicide has a melting point that is greater than about 1,000° C.;
depositing a filler layer onto the wafer surrounding the p-FET gate stack and the n-FET gate stack;
forming first trench contact openings in the filler layer over each of the p-FET source and drain regions;
depositing a second metal onto the wafer and lining the trench contact openings;
annealing the wafer to form a trench silicide in each of the p-FET source and drain regions from the second metal; and
forming second trench contact openings in the filler layer over each of the n-FET source and drain regions.

20. The method of claim 19, further comprising the step of:
forming contacts in the first trench contact openings and in the second trench contact openings.

21-25. (canceled)
